(19) United States
(12) Patent Application Publication
(10) Pub. No.: US 2026/0269796 A1
(43) Pub. Date: Sep. 10, 2026

(54) SYSTEMS AND METHODS FOR LOW POWER CIRCUITS

(71) Applicant: National University of Singapore, Singapore (SG)

(72) Inventors: Joydeep Basu, Singapore (SG); Luigi Fassio, Singapore (SG); Karim Ali Ahmed, Singapore (SG); Massimo Alioto

(21) Appl. No.: 19/491,358

(22) PCT Filed: Jun. 7, 2024
(86) PCT No.: PCT/SG2024/050381

§ 371 Date: Dec. 8, 2025

(30) Foreign Application Priority Data
Jun. 9, 2023 (SG) 10202301637Y

(51) Int. Cl. H03F 3/45; H03F 3/16

(52) U.S. Cl. CPC H03F 3/45475; H03F 3/16; H03F 3/45636; H03F 3/45932

(57) ABSTRACT

In a described embodiment, a super-cutoff current mirror circuit is provided. The super-cutoff current mirror circuit comprising: a first transistor stack, a second transistor stack, and a third transistor stack, wherein each transistor stack comprises one NMOSFET and one PMOSFET, and wherein each transistor stack is configured for super-cutoff transistor operation with a negative NMOSFET gate-source voltage or a PMOSFET source-gate voltage, wherein the circuit is configured such that the first transistor stack conducts input current via a negative feedback loop enabled by the second transistor stack, and the third transistor stack replicates the input current as an output current.

### TECHNICAL FIELD

The present application pertains generally to low-power analog circuits and low-power integrated circuits and systems, and in particular systems and methods for providing circuitry to lower power usage in analog and sensor interfaces.

### BACKGROUND

Ultra-low power circuit techniques are essential for realizing long-lived, mm-scale, and low-cost self-powered systems, particularly in applications with relaxed performance requirements (e.g., bandwidth). Such systems favor usage of a single energy source (either mm-scale micro-batteries or integrated harvesters), thus avoiding the higher cost and form factor of hybrid battery-harvester sources. The lifetime of micro battery powered systems can be made to approach the battery shelf life if the minimum system power (Pₘᵢₙ) can be reduced down to battery leakage which is typically in the pW range. In contrast, purely-harvested silicon systems enable circuit miniaturization, cost reduction, and unrestricted lifespan (e.g. no battery shelf life) thanks to the removal of off-chip energy storage (e.g., battery) along with its typically dominant size and cost. In this regard, purely harvested may refer to systems and circuits that can be purely (i.e., fully) powered using harvested energy i.e., from energy harvesting source(s), and thus, without requiring a battery for power up. Nonetheless, systems with miniaturized harvesters may be forced to shut down frequently, for example whenever system power cannot be supported by the instantaneous harvested power under its wide fluctuations. Uptime extension of such systems requires minimum system power Pₘᵢₙ reduction down to the very low levels of harvested power that are available under unfavorable environmental conditions (e.g. low light for solar harvesting applications).

Analog sub-systems with power/stage down to nWs were explored leveraging low supply voltages and sub-threshold operation, and further power reductions were demonstrated in digital circuits based on super-cutoff transistor operation with gate-to-source voltage V_{GS}<0 V (e.g., entire processors with power in the hundreds of pWs). In applications targeting low speed (e.g., environmental monitoring, food/pharmaceutical tracking), filling this power gap may require specialized analog circuit techniques to support bias currents below regular transistor leakage (i.e., transistor current at V_{GS}=0 V).

Another example of applications of purely-harvested analog sub-systems includes serving as a wake-up trigger of microbattery-powered systems, by keeping their power negligible most of the time, while not adding any power burden. Wake-up receivers in the tens of nWs, nWs and sub-nW range have been demonstrated based on radiofrequency, ultrasonic and optical sensing of wake-up signals from a base station. Further power reductions would allow further shrinking of the harvester down to the mm scale while not sacrificing uptime, as necessary to make wake-up receivers always listening.

Therefore, it is desirable to provide a method and system that leverages low or ultra-low power circuitry, or at the very least, provide the public with a useful alternative.

### SUMMARY

The present disclosure aims to provide new and useful systems and methods for low or ultra-low-power analog circuits and low or ultra-low-power integrated circuits and systems, and in particular systems and methods for providing circuitry to lower power usage in analog and sensor interfaces.

In a first aspect, the present invention proposes a super-cutoff current mirror circuit, comprising: a first transistor stack, a second transistor stack, and a third transistor stack, wherein each transistor stack comprises one NMOSFET and one PMOSFET, and wherein each transistor stack is configured for super-cutoff transistor operation with a negative NMOSFET gate-source voltage or a PMOSFET source-gate voltage, wherein the circuit is configured such that the first transistor stack conducts input current via a negative feedback loop enabled by the second transistor stack, and the third transistor stack replicates the input current as an output current.

In some embodiments, each transistor stack comprises a respective negative gate-source voltage, or source-gate voltage, without requiring a bias voltage that is lower than 0V, or higher than a supply voltage of the circuit.

In a second aspect, the present invention proposes a bias current generator or current reference circuit, comprising: a temperature dependent proportional-to-absolute-temperature (PTAT) voltage generator, a level shifter, wherein the PTAT voltage generator is configured to provide a supply voltage and a gate voltage to transistors of the level shifter, a common source gain stage to amplify an output (hence its temperature coefficient, TC) of the level shifter, and a temperature dependent proportional-to-absolute-temperature (PTAT) current source configured to receive the PTAT output voltage of the common source gain stage thereby providing a temperature compensated current.

In a third aspect, the present invention proposes a super-cutoff operational transconductance amplifier (OTA) circuit for analog signal processing, the OTA circuit comprising: the super-cutoff current mirror circuit as in the first aspect, the bias current generator or current reference circuit as in the second aspect, and a source-coupled transistor pair to receive an input differential signal to the OTA circuit, wherein the circuit is configured such that the current mirror and the bias current generator, enable super-cutoff operation within the OTA.

In some embodiments, the OTA topology can be configured to have either differential or single-ended output.

In some embodiments, an output common-mode voltage is restored to a desired level in the OTA with differential configuration.

In some embodiments the circuit may comprise a super-cutoff level shifter configured to downshift or upshift a voltage waveform based on a voltage value applied between a gate and a source terminal of the level shifter, wherein the circuit is configured such that the current mirror, the bias current generator, and the super-cutoff level shifter enable super-cutoff operation within the OTA

In a fourth aspect, the present invention proposes a super-cutoff pseudo resistor circuit, comprising: a transistor stack, comprising two PMOSFET transistors, or two NMOSFET transistors, wherein voltages applied to the gate terminal of each transistor in the transistor stack are controlled through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack.

In some embodiments the circuit is voltage-independent.

In a fifth aspect, the present invention proposes a super-cutoff up-level or down-level shifter configured to upshift or downshift a voltage waveform based on a voltage value applied between a gate and a source terminal of the up or down level shifter, the up-level shifter or down-level shifter comprising: a source follower stage, and a bias current generator or current reference circuit as in the second aspect, configured to bias the source follower stage with a super-cutoff current.

In a sixth aspect, the present invention proposes a super-cutoff hysteresis comparator circuit, comprising: a pair of super-cutoff current mirror circuits, each super-cutoff current mirror circuit as in the first aspect, wherein the pair of super-cutoff current mirror circuits are configured in a cross coupled mode, and a super-cutoff current reference as in the second aspect, wherein the comparator circuit is configured to provide a digital output signal indicating whether an input signal is above or below a set of hysteresis thresholds.

In a seventh aspect, the present invention proposes a super-cutoff bandpass filter circuit, comprising: a first 2^{nd}-order bandpass filter circuit, the first bandpass filter circuit comprising a pair of 2-stage level shifters on each of a respective positive and negative output of the first bandpass filter circuit, each 2-stage level shifter comprising the up or down level shifter as in the fifth aspect; and a second 2^{nd}-order bandpass filter circuit, the second bandpass filter circuit comprising: a pair of 2-stage level shifters on respective feedback loops of the second bandpass filter circuit, and a pair of 1-stage level shifters on each of a respective positive and negative output of the second bandpass filter circuit, each 1-stage and 2-stage level shifter comprising the up or down level shifter as in the fifth aspect; wherein the first bandpass filter circuit and the second bandpass filter circuit are arranged in a standalone configuration or a cascade configuration.

In an example, the resistors used in each of the bandpass filter circuits may comprise of the pseudo-resistor as described in the fourth aspect.

In an example, the number of level shifters may be higher or lower than as described in the seventh aspect.

In an eighth aspect, the present invention proposes a super-cutoff programmable gain amplifier, comprising: the operational transconductance amplifier circuit as in the third aspect, and the super-cutoff pseudo resistor circuit as in the fourth aspect, a pair of 2-stage level shifters on each of a respective up and down output of the operational transconductance amplifier, each 2-stage level shifter comprising the up or down level shifter as in the fifth aspect.

In an example, the number of level shifters may be higher or lower than as described in the eighth aspect.

In a ninth aspect, the present invention proposes a super-cutoff wakeup receiver system, comprising: a photo detector, a super-cutoff hysteresis comparator circuit as in the sixth aspect, a super-cutoff bandpass filter circuit as in the seventh aspect, and a super-cutoff programmable gain amplifier as in the eighth aspect, wherein the system is configured to: receive an optically modulated signal, comprising data and clock signals, from a basestation (e.g., infrared LED) through the photo-detector, process the signal via the super-cutoff programmable gain amplifier, the super-cutoff bandpass filter, and the hysteresis comparator, allowing for the recovery of both the data and clock signals; and wherein the system further includes a digital logic section that continuously compares a received data with a stored device ID until a matching data is received, triggering an assertion of a wake-up signal.

In a tenth aspect, the present invention proposes a super-cutoff resistive feedback amplifier, comprising: the super-cutoff operational transconductance amplifier (with differential outputs) as in the third aspect, and the super-cutoff pseudo resistor as in the fourth aspect, wherein the pseudo resistor is arranged in a feedback loop of the operational transconductance amplifier.

In an eleventh aspect, the present invention proposes a super-cutoff single-ended OTA based voltage follower comprising: the super-cutoff operational transconductance amplifier (with single-ended output) as in the third aspect, wherein the OTA is arranged in a unity negative feedback loop with unity feedback from the output to the negative input terminal of the OTA, and the external input signal being provided to the positive input terminal of the OTA.

In a twelfth, the present invention proposes a super-cutoff single-ended OTA based resistive feedback amplifier comprising: the super-cutoff operational transconductance amplifier (with single-ended output) as in the third aspect, and the super-cutoff pseudo resistor as in the fourth aspect, wherein the pseudo resistor is arranged in a feedback loop of the operational transconductance amplifier.

In a thirteenth aspect, the present invention proposes a circuit comprising: a current mirror comprising three transistor stacks, a first transistor stack, a second transistor stack, and a third transistor stack, wherein each transistor stack comprises one NMOSFET and one PMOSFET and enables super-cutoff transistor operation with a negative NMOSFET gate-source voltage or a PMOSFET source-gate voltage without requiring a bias voltage that is lower than 0 V or a bias voltage higher than a supply voltage, wherein the first stack conducts input current via a negative feedback loop enabled by the second stack, and the third stack replicates the input current as an output current; a bias current generator or current reference with transistor operation in super-cutoff having temperature compensation and digital tuning, being configured to increase an internally generated control voltage in proportion to temperature value, in order to compensate the strong temperature dependence of the output current source within the generator.

In an embodiment, the system may be further configured as a super-cutoff operational transconductance amplifier (OTA) for analog signal processing applications, wherein the OTA comprises a source-coupled transistor pair configured to receive an input differential signal to the OTA, and wherein the current mirror with three transistor stacks, and the bias current generator, enable super-cutoff operation within the OTA.

In an embodiment, the system may further include a super-cutoff common mode feedback based on an NMOSFET-PMOSFET stack for enabling fully differential operation based on a comparison of the output common mode voltage with an internally generated bias voltage.

In a fourteenth aspect, the present invention proposes a circuit comprising: a voltage-independent super-cutoff pseudo-resistor formed by a stack of transistors, wherein voltages applied to the gate terminal of each transistor in the stack of transistors is controlled through a voltage level shifting operation; a super-cutoff hysteresis comparator using a bias current generator and a NMOS-PMOS stack, the comparator configured to provide a digital output signal indicating whether an input signal is above or below a set of hysteresis thresholds; a second or higher-order super-cutoff filter implemented by the super-cutoff pseudo resistor and a super-cutoff operational transconductance amplifier (OTA), the filter configured for enhancing the performance of the circuit by filtering out unwanted frequencies; and a super-cutoff programmable gain amplifier, the amplifier comprising the OTA and being configured to provide digitally-programmable amplification of signals.

In an embodiment, the circuit may be further configured to function as an ultra-low-power optical wake-up receiver system, wherein the system receives an optically modulated signal, comprising data and clock signals from a basestation through a photo-detector, wherein the received signal is processed by the super-cutoff programmable gain amplifier, the super-cutoff filter, and the comparator blocks, allowing for the recovery of both the data and clock signals; and wherein the system further includes a digital logic section that continuously compares the received data with a stored device ID until a matching data is obtained, triggering an assertion of a wake-up signal.

In a fifteenth aspect, the present invention proposes a method of forming a current mirror, comprising: providing three transistor stacks, a first transistor stack, a second transistor stack, and a third transistor stack, each transistor stack comprising one NMOSFET and one PMOSFET, configuring each of the three transistor stacks to operate in super-cutoff transistor operation by setting a negative NMOSFET gate-source voltage and/or a PMOSFET source-gate voltage, configuring the first transistor stack to conduct input current via a negative feedback loop enabled by the second transistor stack, and configuring the third transistor stack to replicate the input current as an output current.

In a sixteenth aspect, the present invention proposes a method of forming a temperature-compensated current reference circuit, comprising: providing a temperature dependent proportional-to-absolute-temperature (PTAT) voltage generator, the PTAT voltage generator configured to provide a supply voltage and a gate voltage to a level shifter, amplifying an output (hence its temperature coefficient TC) of the level shifter via a common source gain stage, receiving the PTAT output voltage of the common source gain stage thereby providing a temperature compensated current via a temperature dependent proportional-to-absolute-temperature (PTAT) current source, where the PTAT output voltage of the common source gain stage compensates the change in current of the PTAT current source due to temperature variations.

In a seventeenth aspect, the present invention proposes a method of forming an operational transconductance amplifier (OTA) for analog signal processing, comprising: providing a source-coupled transistor pair to receive an input differential signal to the OTA, providing three transistor stacks, a first transistor stack, a second transistor stack, and a third transistor stack, each transistor stack comprising one NMOSFET and one PMOSFET, configuring each of the three transistor stacks to operate in super-cutoff transistor operation by setting a negative NMOSFET gate-source voltage and/or a PMOSFET source-gate voltage, configuring the first transistor stack to conduct input current via a negative feedback loop enabled by the second transistor stack, and configuring the third transistor stack to replicate the input current as an output current, providing a temperature dependent proportional-to-absolute-temperature (PTAT) voltage generator, the PTAT voltage generator configured to provide a supply voltage and a gate voltage to a level shifter, amplifying an output of the level shifter via a common source gain stage, receiving the output voltage of the common source gain stage and providing a temperature compensated current via a temperature dependent proportional-to-absolute-temperature (PTAT) current source, producing an output current that is proportional to a voltage input to the OTA.

In an example, the method further comprises providing a super-cutoff level shifter configured to downshift or upshift a voltage waveform based on a voltage value applied between a gate and a source terminal of the level shifter.

In an eighteenth aspect, the present invention proposes a method of forming a super-cutoff pseudo-resistor, comprising: providing a transistor stack, comprising two PMOSFET transistors, or two NMOSFET transistors, controlling voltages applied to the gate terminal of each transistor in the transistor stack through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack.

In a nineteenth aspect, the present invention proposes a method of forming a hysteresis comparator, comprising: providing a pair of super-cutoff current mirror circuits, wherein the pair of super-cutoff current mirror circuits are configured in a cross coupled mode, providing a temperature compensated super-cutoff current reference, providing a source-coupled transistor pair configured to receive an input differential signal to the hysteresis comparator, and providing a digital output signal indicating whether an input signal is above or below a set of hysteresis thresholds via the pair of super-cutoff current mirror circuits and the temperature compensated super-cutoff current reference.

In a twentieth aspect, the present invention proposes a method for providing a wake-up signal to a system, comprising; receiving an optically modulated signal, comprising data and clock signals, processing the signal via a programmable gain amplifier, bandpass filters, and hysteresis comparators, allowing for the recovery of both the data and clock signals; continuously comparing the received data with a stored device ID until a matching data is received, and triggering an assertion of a wake-up signal upon receipt of the matching data to the stored device ID.

It will be understood that any features of the above systems, circuits or circuit building blocks of aspects 1 to 14 may be combined with any other systems, circuits or circuit building block aspects as recited herein. Similarly, any features of the above method aspects or steps 15 to 20 may be combined with any other method aspects or steps as recited herein.

The above description is provided as an overview of some implementations of the present disclosure. Further description of those implementations, and other implementations, are described in more detail below.

### BRIEF DESCRIPTION OF THE DRAWINGS

Embodiments of the invention will now be explained for the sake of example only, with reference to the following figures in which:

FIG. 1 illustrates a graph of a conventional transistor current vs gate-to-source voltage;

FIG. 2A illustrates a transistor stack according to an example embodiment of the invention disclosed herein;

FIG. 2B illustrates a super-cutoff current mirror circuit according to an example embodiment of the invention disclosed herein;

FIG. 3A illustrates a super-cutoff current reference generator circuit according to an example embodiment of the invention disclosed herein;

FIG. 3B illustrates a super-cutoff current reference generator circuit according to an example embodiment of the invention disclosed herein;

FIG. 3C illustrates a super-cutoff level shifter circuit according to an example embodiment of the invention disclosed herein;

FIG. 4A illustrates a super-cutoff fully-differential operational transconductance amplifier (OTA) circuit according to an example embodiment of the invention disclosed herein;

FIG. 4B illustrates a super-cutoff single-ended operational transconductance amplifier (OTA) circuit according to an example embodiment of the invention disclosed herein;

FIG. 5 illustrates a super-cutoff pseudo-resistor circuit according to an example embodiment of the invention disclosed herein;

FIG. 6 illustrates a super-cutoff hysteresis comparator circuit according to an example embodiment of the invention disclosed herein;

FIG. 7A illustrates a super-cutoff bandpass filter (BPF) circuit according to an example embodiment of the invention disclosed herein;

FIG. 7B illustrates a super-cutoff programmable gain amplifier (PGA) circuit according to an example embodiment of the invention disclosed herein;

FIG. 8A illustrates a super-cutoff optical wake-up receiver system according to an example embodiment of the invention disclosed herein;

FIG. 8B illustrates a digital sub-system of an optical wake-up receiver circuit according to an example embodiment of the invention disclosed herein;

FIG. 8C illustrates data and waveforms associated with an optical wake-up receiver circuit according to an example embodiment of the invention disclosed herein;

FIG. 9 illustrates data associated with a super-cutoff OTA circuit according to an example embodiment of the invention disclosed herein;

FIG. 10 illustrates data associated with a super-cutoff programmable gain amplifier circuit according to an example embodiment of the invention disclosed herein;

FIG. 11 illustrates data associated with a two super-cutoff bandpass filter circuits according to an example embodiment of the invention disclosed herein; and

FIG. 12 illustrates data associated with a super-cutoff comparator circuit according to an example embodiment of the invention disclosed herein.

### DETAILED DESCRIPTION

Embodiments will now be discussed with reference to the accompanying FIGs., which depict one or more exemplary embodiments. These embodiments are described in sufficient detail to enable those skilled in the art to practice the embodiments and it is to be understood that mechanical, logical, and other changes may be made without departing from the scope of the embodiments. Therefore, embodiments may be implemented in many different forms and should not be construed as limited to the embodiments set forth herein, shown in the FIGs., and/or described below.

Herein, the term “super-cutoff” refers to transistors operating at negative NMOSFET gate-source voltage (alternatively PMOSFET source-gate voltage), and operating in a low current conduction range. Put another way, super-cutoff transistor may operate at negative gate-to-source voltage, and yet provide a small current flow (or a negative source-to-gate voltage for PMOSFET and yet provide small current flow). Super-cutoff transistor operation may enable low or ultra-low power circuits with static current that, in an example embodiment, may be below the traditional transistor leakage current.

Herein, the term “harvested” or “harvested system” refers to a system or circuit that is driven using harvested energy, i.e., energy derived from energy harvesting source(s). In conjunction, battery energy sources may also be utilized to provide some of the power requirement to a system, which may be termed a hybrid harvested system.

Herein the term “purely harvested” refers to a system or circuit that can be purely (i.e., fully) powered using harvested energy, i.e., from energy harvesting source(s) only. In one example, this may nullify the need to use a battery to provide energy to a system or circuit.

Furthermore, the claimed subject matter may be implemented as a method, apparatus, or article of manufacture using standard programming and/or engineering techniques to produce software, firmware, hardware, or any combination thereof to control a computer to implement the disclosed subject matter.

Unless otherwise defined, all terms (including technical and scientific terms) used herein are to be interpreted as is customary in the art. It will be further understood that terms in common usage should also be interpreted as is customary in the relevant art.

In an example embodiment, circuit techniques to enable super-cutoff operation in common analog building blocks for operational amplifiers are described that may reduce a bias current below regular leakage by orders of magnitude. Circuit techniques for super-cutoff current mirrors, current references, pseudo-resistors and others are introduced and validated in closed-loop operational transconductance amplifier (OTA) based designs (e.g., amplifiers, filters), showing a power/stage in the pW range and robust operation under unregulated harvested supply. The OTA-based example designs and embodiments are demonstrated in a complete mixed-signal system design for always-on LiFi optical wake-up receiver consisting of blocks from photodetectors to sensor interface, and digital processing for data and clock recovery. In an example embodiment, the system is shown to have near-100% uptime with mm-sized solar cell down to near dark, thanks to its overall power of around 78 pW. Additional details are provided in J. Basu et al., “Picowatt-Power Analog Gain Stages in Super-Cutoff Region With Purely-Harvested Demonstration,” in IEEE Solid-State Circuits Letters, vol. 5, pp. 226-229, 2022; J. Basu, L. Fassio, K. Ali and M. Alioto, “Picowatt-Power Super-Cutoff Analog Building Blocks and 78-pW Battery-Less Wake-Up Receiver for Light-Harvested Near-Always-On Operation,” in IEEE Journal of Solid-State Circuits, vol. 59, no. 4, pp. 1038-1049, April 2024; and J. Basu, L. Fassio, K. Ali and M. Alioto, “Super-Cutoff Analog Building Blocks for pW/Stage Operation and Demonstration of 78-pW Battery-Less Light-Harvested Wake-Up Receiver down to Moonlight,” 2023 IEEE Symposium on VLSI Technology and Circuits (VLSI Technology and Circuits), Kyoto, Japan, 2023, pp. 1-2, all of which are incorporated by reference herein.

Example embodiments of the invention disclosed herein relate to systems and methods to reduce power consumption below or significantly below regular transistor leakage by enabling super-cutoff transistor operation with a negative NMOSFET gate-source voltage or a PMOSFET source-gate voltage. Various circuit building blocks with super-cutoff transistor operation are provided in example embodiments, including super-cutoff current mirror, super-cutoff current reference, super-cutoff OTA (both fully differential and single-ended versions), super-cutoff pseudo-resistor, super-cutoff down- and up-level shifters, and super-cutoff hysteresis comparator. In further example embodiments using the aforesaid building blocks, various circuit topologies are disclosed, including super-cutoff bandpass filter, super-cutoff programmable gain amplifier, super-cutoff resistive feedback amplifier, super-cutoff single-ended OTA based voltage follower, etc. Further, in an example embodiment using such constituent blocks, a super-cutoff optical wakeup receiver is also disclosed.

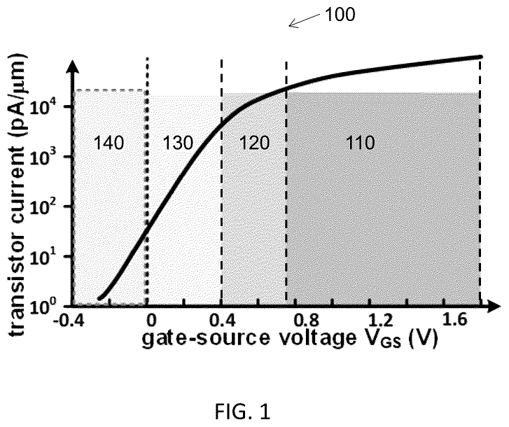

FIG. 1 illustrates a graph 100 of transistor current versus gate-source voltage for a minimum sized MOSFET of 180 nm. It will be understood that use of the term “minimum sized transistor or MOSFET” may refer to a MOSFET having minimum size (dimensions) as allowed in the particular CMOS process i.e., with width=Wₘᵢₙ, length=Lₘᵢₙ as applicable. As is evident, four regions of the graph indicate the operating mode of a transistor. The above-threshold operation 110 is typically above the requisite turn on gate-source voltage, indicating a region where the transistor may be in its conduction mode, and in this case indicated from under about 0.8V to about 1.8V+. The near-threshold operation range 120 indicates a range or transistor current flow between gate-source voltage of about 0.4V, and under about 0.8V, indicating in one example where a transistor may start to enter its conduction mode. The sub-threshold operation range 130 indicates a region of gate-source voltage between about 0V, and about 0.4V, where regular transistor leakage may occur resulting in low current conduction. The super-cutoff operation region 140 indicates a range of low current conduction, in this example embodiment in the picoampere range, where the transistor operates at negative gate-source voltage, yet provides a small current flow.

It will be understood that the gate-to-source voltage (V_{GS}) referred to herein applies as either a negative or a positive voltage depending on the architecture/type of the transistor. For example, the above threshold conduction mode 110 as described above involves a positive gate-source voltage for an n-type MOSFET transistor, and a corresponding negative gate source voltage for a p-type MOSFET transistor. It will therefore be understood that a “negative” gate-source voltage applied to an n-type MOSFET will be a truly negative voltage, however, a “negative” gate-source voltage applied to a p-type MOSFET may refer to the inverse of the “normal” or above-threshold (110) operating voltage V_{GS}, and in an example embodiment would therefore comprise a small positive voltage, to place the p-type MOSFET transistor in the super-cutoff operating mode 140.

In an example embodiment, purely-harvested sensor nodes may enable low cost devices, at least due to an ability to eliminate off-chip expensive components (such as batteries). Purely-harvested sensor nodes may also enable a small form factor, at least due to allowing a small harvester (dimensions in the ~ mm range). Purely-harvested sensor nodes may also enable a long uptime, at least by pushing the minimum system power down to the minimum harvested power. By reducing Pₘᵢₙ, systems such as with solar harvested power may enable longer or even 100% uptime, where a lowered power consumption may reduce the Pₘᵢₙ value to at or below the minimum harvested/generated power.

Example embodiments of the invention as disclosed herein may provide for analog building blocks in super-cutoff (V_{GS}<0V) for pW/stage power. Example embodiments may enable new circuit techniques, for example where conventional sub-threshold design techniques may be unsuitable for V_{GS}<0V. Example embodiments of the invention as disclosed herein may comprise one or more building blocks in the following applications:
Operational transconductance amplifier (OTA)
Current reference
Current mirror
Pseudo-resistor
Filter
Amplifier
Comparator

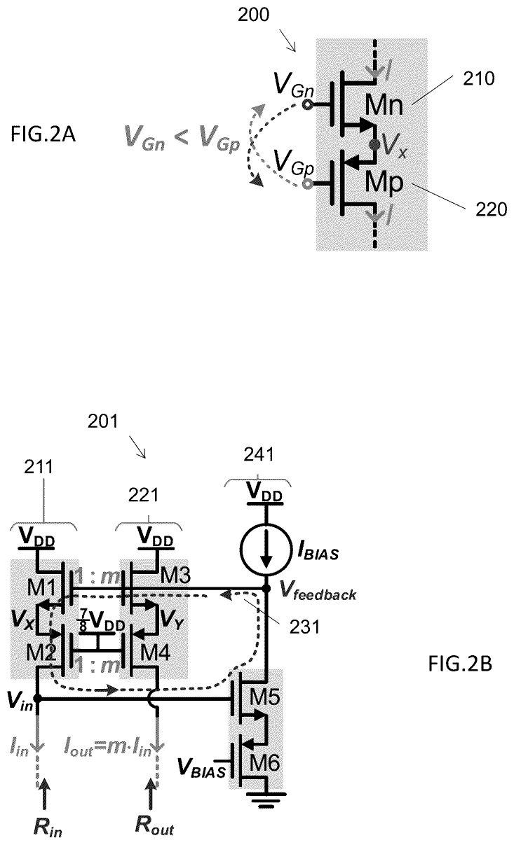

FIGS. 2A and 2B show example embodiments of circuit techniques that may enable super-cutoff operation (V_{GS}<0), for example without requiring any voltage beyond the supply rails. The circuits are shown as representative OTA building blocks.

FIG. 2A illustrates a NMOS-PMOS stack 200, which may comprise transistors (optionally balanced transistors, for example size balanced), Mₙ 210, which may be an NMOS transistor, and Mₚ 220, which may be a PMOS transistor. Stack 200 may be provided to enable super-cutoff transistor operation, optionally without requiring any bias voltage (V_{Gn}, V_{Gp})<0 or >V_{DD}.

The series connection of transistors 210 and 220 yields the following equation, where the equal currents of the respective transistors in weak inversion are:

$${I}_{0 , n} {e}^{\frac{{V}_{Gn} - {V}_{x} - {V}_{TH , n}}{nkT / q}} = {I}_{0 , p} {e}^{\frac{{V}_{x} - {V}_{Gp} - \vert {V}_{TH , p} \vert}{nkT / q}}$$

Where I₀ is a technology-dependent constant including the transistor aspect ratio W/L, V_{TH} is the transistor threshold voltage, n is the sub-threshold factor (assumed to be equal), and kT/q is the thermal voltage. The above expression of current is valid assuming the factor (1−e^{-(VDS)/(kT/q)}) is approximately 1, which requires appropriate choice of the drain to source voltage VDS≥4 kT/q≈100 mV. Sizing the two transistors symmetrically for I_{0,n}=I_{0,p}=I₀ and considering V_{TH,n}≈|V_{TH,p}|≈V_{TH}, the voltage Vx results in (V_{Gn}+V_{Gp})/2 as shown below,

$${V}_{x} = \frac{{V}_{Gn} + {V}_{Gp}}{2}$$

and the resulting current I is:

$$I = {I}_{0} {e}^{\frac{\frac{{V}_{Gn} - {V}_{Gp}}{2} - {V}_{TH}}{nkT / q}}$$

From this equation, the stack as disclosed herein may behave like a single transistor, with V_{GS}=(V_{Gn}+V_{Gp})/2, which can be made negative by setting V_{Gp}>V_{Gn} and with the voltages V_{Gp} and V_{Gn} within the supply rail voltages. This provides for an example embodiment of a super-cutoff stack, and is used herein as a building block for the circuit topologies disclosed herein.

Put another way, in an example embodiment, FIG. 2A shows the NMOS-PMOS stack which may provide a current that is equivalent to a single transistor with V_{GS}<0 while not requiring any voltage beyond the supply/ground rail voltage, as long as the NMOS gate voltage is kept lower than the PMOS one.

FIG. 2B illustrates a current mirror 201, which may operate in super-cutoff as described herein. The example embodiment in FIG. 2B illustrates three transistor stacks, which may each comprise a respective NMOS-PMOS stack, such as that illustrated in FIG. 2A configured to operate in super-cutoff.

The first stack 211 may comprise input transistors, indicated as M1 and M2 in FIG. 2B. The second stack 221 may comprise mirroring transistors, indicated as M3 and M4. In an example embodiment, the current mirror 201 may enable super-cutoff operation by pairing two NMOS-PMOS stacks, i.e. stack 211 (M1-M2) and stack 221 (M3-M4), where stack 211 (M1-M2) conducts the input current Iᵢₙ due to a negative feedback loop 231 in current mirror circuit 201, in an example embodiment by adjusting the gate voltage of M1 and M3 accordingly.

In an example embodiment, the stack 221 (M3-M4) replicates the current in stack 211 (M1-M2) to ultimately mirror the input current to the output with the intended current ratio set via ordinary ratioed sizing in transistors M1-M4. In an example embodiment, V_{feedback} is set by the negative feedback loop 231 to make I_{M1,2}=Iᵢₙ.

In the example super-cutoff current mirror embodiment of FIG. 2B, the super-cutoff common-source stage 241 (M5-M6) may be a gain stage biasing and feedback loop closure stage. The stage 241 (M5-M6) may enforce the negative feedback loop 231, and may introduce a gain that further reduces the small-signal input resistance Rin. In an example embodiment, stage 241 (M5-M6) may comprise a super-cutoff common source amplifier, and may have a gain—A, which increases loop gain.

In an example embodiment of the current mirror circuit in FIG. 2B, the input and output small-signal resistances are Rᵢₙ=(1/gₘ₁)*(2/A), and Rₒᵤₜ=2r₀₄.

A current mirror operating in super-cutoff can be realized as shown in FIG. 2B. However, a straightforward replacement of each transistor in a conventional current mirror with the super-cutoff stack may not operate correctly, due to the presence of a positive feedback loop gain. To turn this loop into negative feedback, the super-cutoff inverting (common-source) stage comprising M5-M6 at 241 may be introduced.

The stack M1-M2 at 211 may conduct the input current Iᵢₙ, due to the negative feedback loop 231, which adjusts the gate voltage of M1-M3 to keep the current of M1-M2 (211) constant and equal to the input current Iᵢₙ. From the equation below, the mirroring stack M3-M4 at 221 replicates the sum of VGS of M1-M2:

$${V}_{GS 1} + {V}_{SG 2} = {V}_{GS 3} + {V}_{SG 4}$$

which in turn mirrors the input current to the output current Iₒᵤₜ with the intended current ratio set via ordinary ratioed sizing m (i.e., ratio of M3-M4 and M1-M2 aspect ratios):

$${I}_{out} = m \cdot {I}_{0} {e}^{\frac{\frac{{V}_{GS 1} + {V}_{SG 2}}{2} - {V}_{TH}}{nkT / q}} = m \cdot {I}_{i n}$$

An advantage that may be provided by the inverting stage M5-M6 241 is that the gain of this stage may help increase the loop gain and hence reduce the input resistance Rᵢₙ=2/(gₘ|A|)=2/(gₘ·(gₘrₒ)). Additionally, the output resistance Rₒᵤₜ is 2rₒ and is unaffected by the loop. In an example embodiment (not shown), a complementary (i.e., current-sink) version of the current mirror may be realized by mirroring the circuit between the power rails.

In example embodiments, the voltage headroom of the current mirror 201 may be reduced by the minimum voltage drop across the NMOS-PMOS stack. For example, the minimum allowed NMOS drain-source (PMOS source-drain) voltage for operation in saturation may be ~100 mV. In this example, the minimum voltage drop across the NMOS-PMOS stack from NMOS drain and PMOS drain (as shown in FIG. 2A) is ~200 mV, which may limit the voltage headroom of the current mirror output of circuit 201 in FIG. 2B as VDD-200 mV.

As set out above, in example embodiments, the NMOS-PMOS stack 200 in FIG. 2A is shown to provide a current that is equivalent to a single transistor with V_{GS}<0, while not requiring any voltage beyond the supply/ground rail voltage, as long as the NMOS 210 gate voltage is kept lower than the PMOS 220 gate voltage. The proposed current mirror 201 in FIG. 2B may enable super-cutoff operation by pairing two NMOS-PMOS stacks 211 (M1-M2) and 221 (M3-M4), where stack 221 (M1-M2) conduct the input current Iᵢₙ thanks to the negative feedback loop in FIG. 2B (adjusting the gate voltage of M1-M3 accordingly). As explained in the circuit analysis above for FIG. 2B, the stack 221 (M3-M4) replicates the current in the stack 211 (M1-M2) to ultimately mirror the input current to the output with the intended current ratio set via ordinary ratioed sizing in M1-M4. The super-cutoff common-source stage 241 (M5-M6) may enforce negative feedback, and introduce a gain that further reduces the small-signal input resistance of the current mirror, and which adjusts the gate voltage of M1-M3 to keep the current of M1-M2 constant and equal to the input current Iᵢₙ.

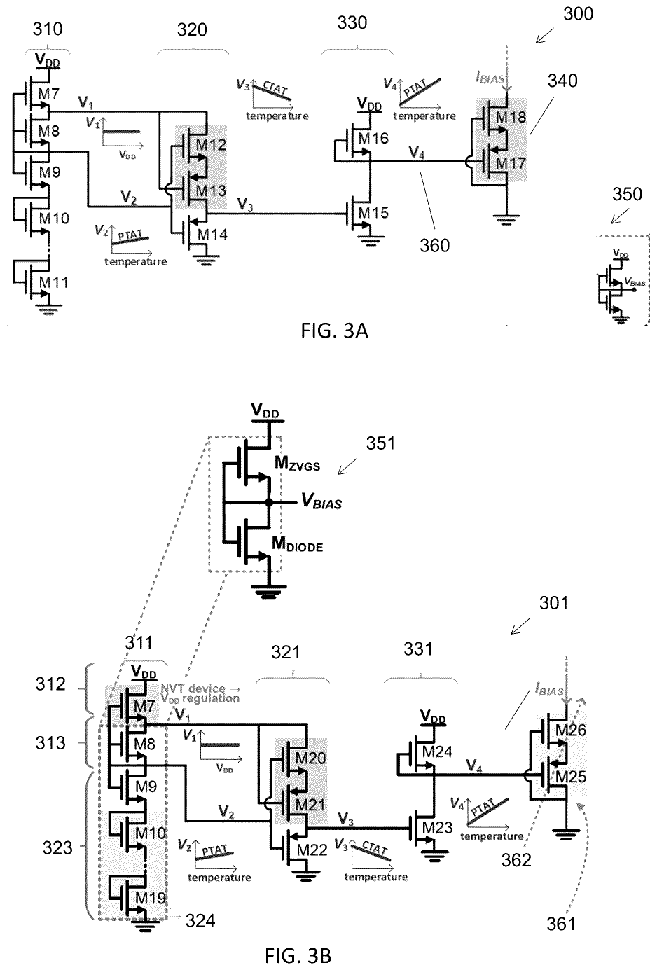

FIG. 3A illustrates an example embodiment of a temperature-compensated digitally-adjustable bias current (I_{BIAS}) generator 300 according to an example embodiment of the invention. In an example embodiment, temperature compensated I_{BIAS} generation and digital adjustment is provided, with the principle of PTAT voltage V₄ quenching PTAT current source based on an NMOS-PMOS stack, such as the stack 200 as illustrated in FIG. 2A. The digitally-adjustable bias current generator 300 may enable process corner compensation (based on on-chip process sensor), and help in adjusting for power-bandwidth tradeoff.

In an example embodiment, the generation of V₁ and V₂ (proportional-to-absolute-temperature (PTAT) voltage) may be provided by transistors M7-M11, indicated as stack 310. In an example embodiment, M7 makes V₁ independent of V_{DD} (voltage supply).

In an example embodiment, stack 320 may comprise a level shifter, comprising transistors M12, M13, and M14. The level shifter 320 may comprise a level shifter with CTAT temperature dependence of V₃, where the level shifter may amplify the temperature sensitivity of V₃ (temperature coefficient (TC) of M14 is different from the stack M12-M13).

In an example embodiment, common-source gain stage stack 330 may comprise transistors M15 and M16, and may magnify the PTAT temperature sensitivity of V₄.

In an example embodiment, the stack 340 may comprise a strongly PTAT current source compensated by the strongly PTAT V₄ as set out above. Digital adjustment may be provided by M17-M18 being digitally controlled to adjust the bias current. In an example embodiment, this may enable process corner compensation across OTAs using I_{BIAS}, and may help in adjusting for power-bandwidth tradeoff. Temperature compensation may be provided as M17-M18 has a strongly PTAT temperature dependence (exponential), resulting in temperature induced increase in V₄ compensating the current increase of M17-M18 to reduce the TC of I_{BIAS}.

In an example embodiment as shown in FIG. 3A, long-channel transistors may be used. In an example embodiment, the cascaded stages (V₂→V₃→V₄) amplify temperature sensitivity of V₄ (PTAT) to compensate the strong temperature dependence of M17-M18, leading to low TC in I_{BIAS}. Reference 350 indicates a 2-transistor temperature compensated V_{BIAS} generator.

In an example embodiment, the temperature-compensated bias current generation in FIG. 3A may reduce the traditionally strong temperature dependence of current sources by increasing the control voltage V₄, indicated by reference numeral 360 in FIG. 3A, with temperature. The strong temperature dependence of the output current source stack 340, M17-M18, may be mitigated with a proportional-to-absolute-temperature (PTAT) voltage V₄ 360 with targeted sensitivity of 2 mV/° C. The latter may be achieved by amplifying the PTAT dependence of voltage V₂ through various stages adding both temperature sensitivity (320, 330, i.e. M12-M14, M15-M16) and voltage gain (330, M15-M16), while using the regulated voltage V1 as supply of the level shifter 320 (M12-M13) to allow operation with unregulated system supply. The inverting stage 330 M15-M16 may generate the desired voltage V₄ 360 with sensitivity of 2 mV/° C., where the V₄ 360 increase with temperature reduces V_{SG} in the M17-M18 stack and hence mitigates the output current increase at higher temperatures (in an example embodiment, the sensitivity may be 10 fA/° C.).

FIG. 3B illustrates an example embodiment of a voltage and/or current reference 301 as described herein. The two-transistor (2-T) structure 351 in FIG. 3B can be used as a building block to generate both temperature compensated bias currents and voltages with transistors in super-cutoff.

As is evident, 351 may be replaced by stacked diode-connector NMOS transistors 323 to increase V_{BIAS}. In an example embodiment, the stack diodes may be equivalent to a single M_{DIODE} with longer channel. TC may be adjusted by sizing. Reference 324 indicates the stacked extra diode devices may increase V₂.

Section 311 may generate V₁ and V₂ (PTAT). Section 321 may comprise a level shifter with CTAT temperature dependence of V₃. Section 331 may comprise a common-source gain stage.

The structure 351 in FIG. 3B may generate a proportional-to-absolute-temperature PTAT (complementary to-absolute-temperature, CTAT) voltage if the length of the diode-connected transistor M_{DIODE} is larger (smaller) than that of the zero-VGS transistors M_{ZVGS}, shown as reference 313. For bias current generation, a modified version of the building block 351 may be used to partially compensate the exponential temperature dependence of the current in weak inversion. The latter is evaluated with the transistor being biased with constant gate voltage as in 301 (see current I_{BIAS}). In an example embodiment, M9 . . . M19 comprise 11 diode-connected NMOS transistors implementing M_{DIODE} of 351 with an increased effective channel length, as necessary to bring voltage V₂ up to the desired value. It will be understood that any number of diode-connected NMOS transistors may be implemented as necessary to bring voltage V₂ up to the desired value. In an example embodiment, voltage V₂ may have a value of about ~130 mV in this example, while keeping its bias current below the pA level.

M8-M19 may generate a PTAT voltage V₂, whereas their effective supply voltage V₁ may be self-regulated (i.e., largely supply voltage-independent), due to the insertion of the native transistor M7 at 312. In an example embodiment, voltage V₁ may have a slightly higher temperature coefficient (TC) compared with V₂, which may contribute to further compensate the above I_{BIAS} increase with temperature. In an experimental example, voltage V₁ may have a slightly higher temperature coefficient (TC) of 0.48 mV/° C. compared with 0.42 mV/° C. in V₂, which, as set out above, may contribute to further compensate the above I_{BIAS} increase with temperature.

In an example embodiment of FIG. 3B, the inverting level shifter M20-M22 transforms V₂ into the CTAT voltage V₃ with negligible dependence on the supply voltage, since the level shifter supply is taken from the self-regulated voltage V₁. The otherwise strong temperature dependence of transistors M25-M26 delivering the output current may finally be compensated by generating the PTAT voltage V₄ with increased TC through the voltage gain in the common-source stage M23-M24, indicated at 361. Digital adjustment, i.e. digital enablement of transistor replicas, is indicated at 362. Overall, cascading the above stages may enable a temperature coefficient increase, which in an example embodiment may nearly compensate the temperature coefficient of the voltage-to-current conversion in M25-M26. In an example embodiment, cascading the above stages may enable a temperature coefficient increase from 0.42 mV/° C. in V₁ to 2 mV/° C. in V₄, which in an experimental example may nearly compensate the temperature coefficient of the voltage-to-current conversion in M25-M26 to 10 fA/° C.

In an example embodiment, the bias current can be further adjusted for different targets via digital enablement of M25-M26 parallel replicas, increasing the transistor multiplicity when PMOS threshold increases and vice versa. Similar considerations hold for the complementary version of bias current source, where a 2-T PMOS bias voltage generator may provide a CTAT voltage to drive an NMOS current source. In an example, the building block 351 may be adopted in view of its substantially improved line sensitivity over conventional two-transistor references as necessary for their adoption under unregulated harvested voltages. FIG. 3C illustrates an example embodiment of super-cutoff level shifters 212 and 222. In an example embodiment, level shifters are provided with conventional common-drain stages, although their V_{GS}<0 may mandate the use of a PMOS (NMOS) stage for down (up) shifting, respectively, (i.e. opposite to conventional or prior art designs with V_{GS}>0).

Level shifters in super-cutoff, such as 212 and 222, may be realised using a conventional source follower stage biased with a super-cutoff current as in FIGS. 3A and 3B, discussed in more detail below. This leads to NMOS (PMOS) negative V_{GS} (V_{SG}), which inherently shifts the output voltage up (down) as shown in FIG. 3C. Put another way, in an example embodiment super-cutoff level-shifting can be implemented as in sub-threshold circuits, with the only difference being the opposite type of transistor. In an experimental example, level-shifting of ~100 mV per stage may be achieved with the adopted 180-nm technology at pA-level bias current. It will be understood that these experimental values are representative, and may be any other value based on the specific design requirements. Level shifters of FIG. 3C may be obtained with conventional common-drain stages, although their V_{GS}<0 may mandate the use of a PMOS (NMOS) stage for down (up) shifting (opposite to common designs with V_{GS}>0).

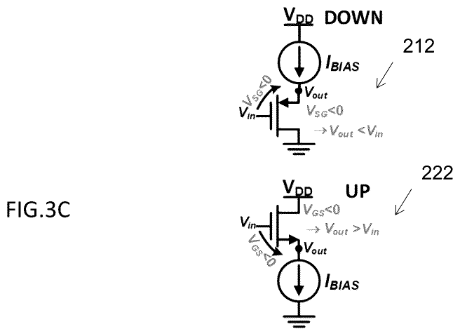

FIG. 4A illustrates an example of OTA 400 based on the building blocks (super-cutoff current mirrors, current and voltage references) illustrated in FIGS. 2A to 2B, and FIG. 3A or FIG. 3B. In an example embodiment, a complete super-cutoff OTA 400 may comprise common-mode feedback (CMFB) circuit comprising transistors M23-M26 operating in the super-cutoff region for fully-differential operation, which subtracts part of the tail bias current when the output common mode is lower than their bias voltage. Put another way, the common-mode feedback of M23-M26 subtracts more (alternatively less) current from the tail to increase (alternatively reduce) common mode output when it goes below (alternatively above) V_{G23}=V_{G25}. This may result in an increase (decrease) in the net bias current being provided to the source-coupled pair M21-M22, which may restore the output common-mode voltage back down (up) to the original value as desired.

FIG. 4B illustrates an example of OTA 401 based on the building blocks (super-cutoff current mirrors, current and voltage references) illustrated in FIGS. 2A to 2B, and FIG. 3A or FIG. 3B. In an example embodiment, the OTA 401 may comprise a single-ended super-cutoff OTA version of the OTA 400 as disclosed in FIG. 4A, and may comprise a super-cutoff current mirror serving as active load for the two output branches of the source-coupled pair M7, M8. In an example embodiment, the sub-circuit shown as reference 411 is the current mirror active load.

The CMFB circuit 410 as indicated in FIG. 4A may be based on the current feedback and may steer away part of the tail bias current when the common-mode output deviates from V_{BIAS}. In particular, an increase (decrease) in the common-mode output leads to a decrease (increase) in the current I_{CMFB} generated by the CMFB circuit and being subtracted from the tail current, as in FIG. 4A. This may result in an increase (decrease) in the net bias current being provided to the source-coupled pair M21-M22 (in FIG. 4A, or M7-M8 in FIG. 4B), which may restore the output common-mode voltage back down (up) to the original value as desired. In an experimental example using the example design used in the fully differential OTA 400 in FIG. 4A with under 0.5-V supply (VDD) sets the output common-mode level at ~300 mV. Regarding the input common-mode range, in an experimental example it may be centered around 0 V and may range from −50 to 90 mV under the same supply voltage. It will be understood that these experimental values are representative, and may be any other value based on the specific design requirements.

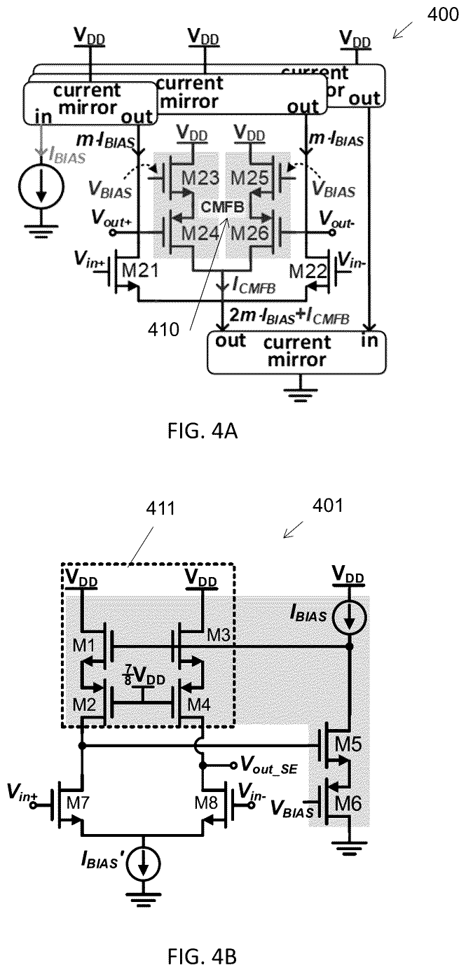

In an example embodiment, pseudo-resistors are provided for closed-loop configurations. In an example shown in FIG. 5, a voltage-independent super-cutoff pseudo-resistor 500 is provided, which may be based on two stacked transistors, for example stacked PMOS-PMOS transistors, as indicated by transistor stack 510. In an example embodiment, the two gate voltages for stack 510 are dynamically set through level shifting. For example, by up level shifting to maintain V_{SG} negative and constant in the transistor that dominates the overall resistance, depending on the voltage V_{A}−V_{B} across the pseudo-resistor.

In an example embodiment, NMOS (UP) level shifter 520 maintains the gate voltage of transistor MA of stack 510, and NMOS (UP) level shifter 530 maintains the gate voltage of transistor MB of stack 510. In an example embodiment, up level shifter 520 may keep V_{SG} of transistor MA of stack 510 constant and negative for super-cutoff operation as described herein. Similarly, up level shifter 530 may keep V_{SG} of transistor MB of stack 510 constant and negative for super-cutoff operation as described herein.

In an example, the on resistance R_{A} in the linear region of transistor MA may be set by V_{SG,A}. Similarly, in an example, the on resistance R_{B} in the linear region of transistor MB may be set by V_{SG,B}.

In an example embodiment, as indicated by item 540 showing an approximation of the circuit 500, if V_{A}−V_{B}>0, then V_{A} is the voltage at the source of MA, and V_{B} is the voltage at the drain of MB. In this case the level shifter MLA controls V_{SG} in MA, whereas MB has 0>V_{SG,B}>V_{SG,A} and MB's on-resistance is much smaller than MA. This sets the overall resistance to a fixed value set by the V_{GS} of the level shifter, regardless of the voltages V_{A} and V_{B} at the two pseudo-resistor terminals.

Put another way, if V_{A}−V_{B}>0, where V_{A} is the voltage at the source of MA, and V_{B} is the voltage at the drain of MB. In this case, MA is in super-cutoff, with V_{SG,A}<0 set by MLA (a large R_{A}). MB has 0>V_{SG,B}>V_{SG,A} (a small RB), and overall the resistance (R_{A}+R_{B}) is kept constant, regardless of V_{A} and V_{B}.

Similarly, in an example embodiment, as indicated by item 550 showing an approximation of the circuit 500, if V_{A}−V_{B}<0, then V_{A} is the voltage at the drain of MA, and V_{B} is the voltage at the source of MB. In this case the level shifter MLB controls V_{SG} in MB, whereas MA has 0>V_{SG,A}>V_{SG,B} and MA's on-resistance is much smaller than MB. This sets the overall resistance to a fixed value set by the V_{GS} of the level shifter, regardless of the voltages V_{B} and V_{A} at the two pseudo-resistor terminals.

Put another way, if V_{A}−V_{B}<0, V_{A} is the voltage at the drain of MA, and V_{B} is the voltage at the source of MB. In this case, MA has 0>V_{SG,A}>V_{SGB} (a small R_{A}), and MB is in super-cutoff, with V_{SG,B<0} set by MLB (a large R_{B}). In this case the overall the resistance (R_{A}+R_{B}) is kept constant, regardless of V_{A} and V_{B}.

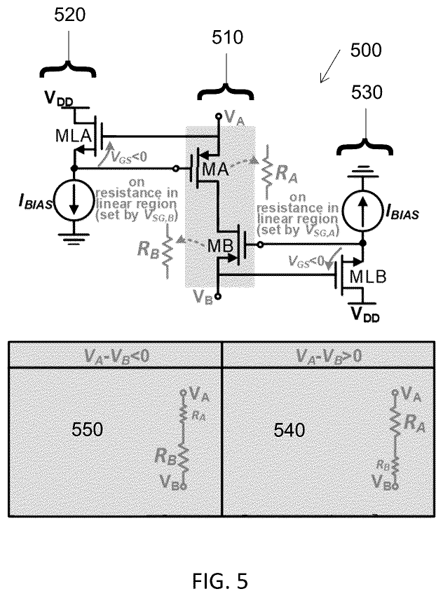

FIG. 6 illustrates an example embodiment of a hysteresis comparator 600, which may use some of the circuit blocks disclosed herein, for example those shown in FIGS. 2A to 2B, and FIG. 3A or FIG. 3B (super-cutoff current mirrors, current and voltage references). In an example embodiment, FIG. 6 illustrates a super-cutoff hysteresis comparator, and includes a number of transistor stacks 601, such as NMOS-PMOS stack 200 as disclosed in FIG. 2A, that may be provided to enable super-cutoff transistor operation. In an example embodiment, I_{BIAS} 610 may be a complementary version of I_{BIAS} as indicated in the example embodiments of FIGS. 3A and 3B. Similarly, V_{BIAS} 620 is a similarly generated version of V_{BIAS} as indicated in the example embodiments of FIGS. 3A and 3B, in an example, V_{BIAS}~(½)V_{DD} (620) and V_{BIAS2}~(⅞)V_{DD} (621). In this example embodiment, 630 and 640 are cross-coupled current mirrors, and positive feedback is provided for hysteresis.

In an example embodiment, an extra negative feedback path could also be introduced to circuit 600 to reduce thresholds (not shown).

In the example embodiment of FIG. 6, a complementary current mirror 660 is indicated. Similarly, a source-coupled transistor pair is indicated at 670 where an input differential signal may be applied to the comparator 600.

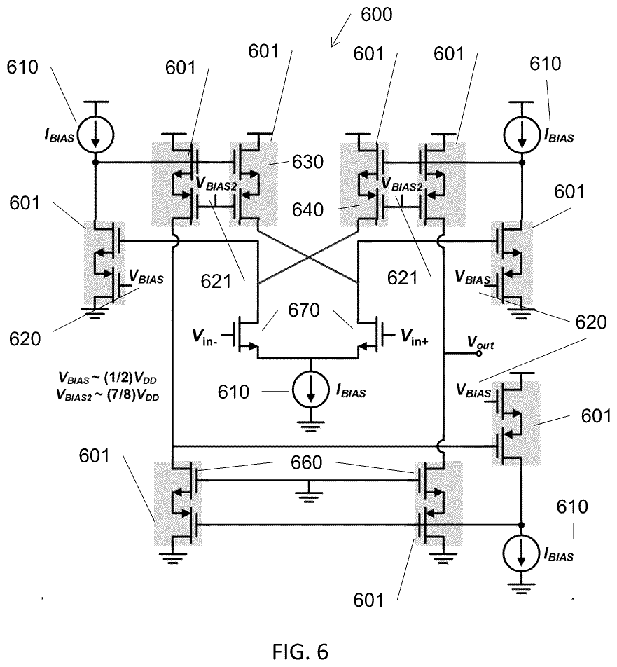

FIG. 7A illustrates an example embodiment, of a 2^{nd} or higher order filter 700, for example a super-cutoff 4^{th} order bandpass filter in this example, realised by cascading two 2^{nd}-order band pass filters 710 and 720. The bandpass filter may use the fully differential OTA as disclosed in FIG. 4A, and pseudo resistors as disclosed in FIG. 5. In this example embodiment, 1LS indicates 1-stage level shifter, and 2LS indicates 2-stage level shifter. In an experimental example the elementary capacitor C may be set to 50 fF, and the filter center frequency (f0) may be adjusted using an elementary pseudo-resistor R (in an experimental example with a value of 4.5 TΩ) downscaled to R/8, . . . , R/2 via transistor sizing. As the resistance may be determined by the bias current I_{BIAS} (FIG. 5), the same considerations regarding PVT variations in gain stages may apply to pseudo-resistors. In an example, process variations are compensated via bias current trimming, voltage variations are mitigated by the adopted voltage-independent pseudo-resistor scheme, and temperature compensation is inherently carried out by the temperature-compensated current reference such as those described in FIGS. 3A and 3B. Overall, this may lead to a minor variation (in an example embodiment, about ~16.7%) in the filter center frequency across PVT variations, which in an example embodiment may have no effect on the intended WuRx operation as descried herein. It will be understood that these experimental values are representative, and may be any other value based on the specific design requirements.

As shown in FIG. 7A, additional level shifters are required to match the output and the input common mode, as the former is higher as discussed above. This general consideration may apply to any feedback configuration, and to the cascading of multiple configurations as in FIG. 7A. Thanks to their low output resistance (1/gₘ) compared with that of an OTA (~rₒ), level shifters in FIG. 7A may push poles associated with feedback passives and load (due to the following stage) to a much higher frequency, which may improve closed-loop stability.

In an example embodiment 700, a design with a 1-Hz center frequency has R₁=R/2, R₂=R, C=50 fF. In an example embodiment, a design with a 4-Hz center frequency has R₁=R/8, R₂=R/4, C=50 fF. In this example, the resistance R being the resistance of the basic pseudo-resistor (changed via sizing), and C is the basic MOM capacitance.

FIG. 7B illustrates an example embodiment of an AC-coupled digitally programmable gain amplifier (PGA) 701, such as a super-cutoff AC-coupled digitally programmable gain amplifier.

In an example embodiment, The AC-coupled digitally programmable gain amplifier (PGA) in FIG. 7B may use the fully differential OTA as disclosed in FIG. 4A, and pseudo resistors as disclosed in FIG. 5.

In an example embodiment, a programmable voltage gain Am being defined by the capacitor ratio C1/C2 is illustrated. In an example embodiment, the PGA may provide for an option of having voltage gain of either 2V/V, 4V/V, 6V/V or 8V/V (i.e., programmable options). It will be understood that these options are indicative (arbitrary) values and can be designed to be any other V/V amplified value as required.

In the example embodiment of FIG. 7B, the programmable gain settings (2×, 4×, 6×, and 8×) may be selectable via switches realized with PMOS transistors with body connected to the supply rail to avoid adding the additional leakage through the n-well/p-subjunction to the signal path. The ac-coupled nature of the PGA may make it easier to achieve a wider gain range via direct cascading. The lower cutoff frequency of the PGA 701 may be determined by the resistor and capacitor in the feedback paths indicated at 711. As discussed above, level shifters may be required to match the common-mode range of the output and the input OTA ports, and a compensation capacitor may be provided to ensure feedback loop stability. In an example embodiment (not shown), a single-ended version of this circuit may be implemented by using the super-cutoff OTA as described in regard to FIG. 4B. Other super-cutoff amplifier configurations such as voltage follower and amplifiers with (pseudo)resistive feedback may also be provided by inserting the abovementioned building blocks into conventional OTA-based architectures.

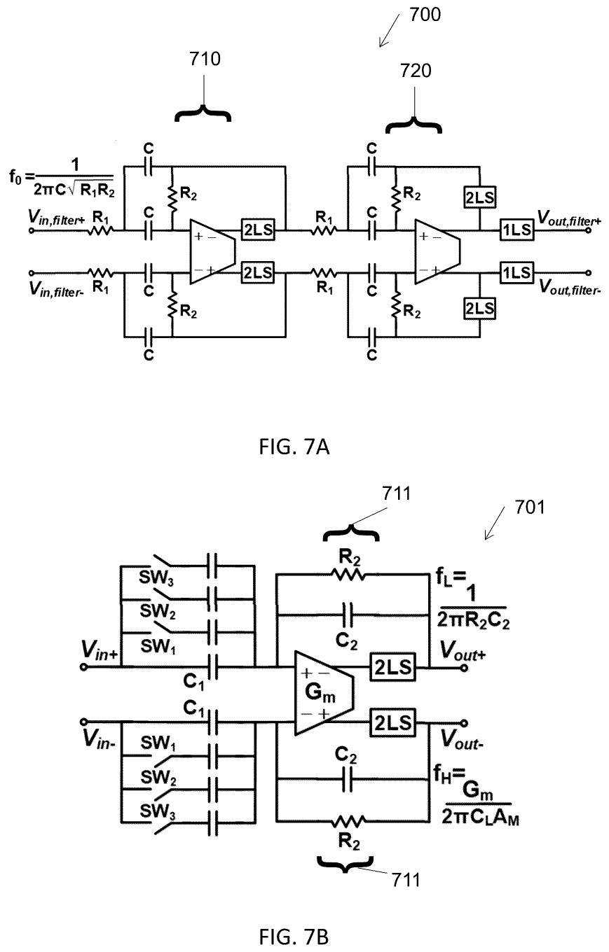

In an example embodiment, the proposed super-cutoff circuit techniques as described herein may be utilised in purely-harvested systems. In an example embodiment, as shown in FIG. 8A, a sub-100 pW optical wake-up receiver (WuRx) system 800 for light fidelity (LiFi) communications is demonstrated in 180 nm CMOS. The example embodiment may comprise an LED basestation 810, for example a basestation LED that transmits at 770-nm, 850 nm, or any infra-red wavelength outside the visible spectrum, although still detectable by silicon photodetectors, such as photodetector 820, which may provide for an inexpensive and compact solution. The transmitted signal may be modulated around two frequencies, i.e. for data and clock 815 as shown in FIG. 8A. The data may be transmitted via on-off keying at f₁=1 Hz, whereas the clock may comprise a single tone at f₂=4 Hz, as shown at 815. The system 800 may comprise a programmable gain amplifier 830, which may comprise one or more super-cutoff analog circuit blocks as disclosed herein. The system 800 may comprise bandpass filters 840, 850, and in an example embodiment, the bandpass filter 1 840 may comprise center frequency f₁=1 Hz, and the bandpass filter 2 850 may comprise center frequency f₂=4 Hz. After photodetector signal amplification via PGA 830, data (clock) recovery may be performed through bandpass filtering, for example 4th-order bandpass filtering around f₁ (at 840) or f₂ (at 850). The bandpass filters 840, 850 may feed the signal to hysteric comparators 860, 870, which may comprise one or more super-cutoff analog circuit blocks as disclosed herein. In an example embodiment, the signal may undergo hysteresis thresholding for on-off keying demodulation at 860, 870.

In an example embodiment, data recovery may follow the upper path 845, and clock recovery may follow the lower path 855.

The signal may then be combined at digital logic 880. In an example embodiment, digital logic 880 may comprise super-cutoff digital logic, which may compare the four time-shifted versions of the data pattern aligned with four subsequent clock phases, and trigger wake-up via wake-up signal 890 when the resulting pattern in any of the phases matches the ID of the considered system (i.e., the basestation aims to wake up that specific node). In an example embodiment, a priority encoder resolves cases where multiple phases correctly match the ID, and a sticky bit may be subsequently generated. The WuRx may then be reset to start listening again to wake-up signals.

In an example embodiment, FIG. 8B illustrates a digital sub-system, such as system 880 of FIG. 8A, recovering data and clock from an optical modulated signal sent by a basestation (e.g. LED) at (in an experimental example an infrared wavelength LED, such as an LED with 770-nm wavelength) and wake-up signal detection process. In an example embodiment, four clock phases (φ₁, φ₂, φ₃ and φ₄) are generated from the received clock signal (CLK) by using a T-flip flop based clock divider. These four clocks are used to sample the received data signal (Data_{IN}) to generate four corresponding sampled data versions (Dataₙ) where n=1, 2, 3 and 4, using 9 bit shift registers 811, where in an example embodiment, the shift registers include comparison and match, producing output as match1 to match4.

As the delay between the received clock and data signals can be different, four different clock phases are generated from the received clock that may allow the acquisition of data based on these phases at the same time. The acquired data may then be compared using 9 bit shift register 811 with comparison match to see if any of the four data match the device ID stored on the chip. If any of the four data matches, it may be determined which phase among these is the correct phase, which may then be used as the clock and the corresponding Dataₙ as the appropriate data signal, as selected using multiplexers 831. In an example embodiment, the wakeup signal is also activated to wake up the rest of the system for further processing. Reference 851 indicates the correct data selection and clock selection, respectively, into multiplexers 831. Reference 861 indicates the clock divider with 4-phase generator, and in an example embodiment may comprise a clock CLK of 4 Hz from the comparator. The data stream, Data_{IN}, and clock, CLK, are indicated at 841, and may comprise the signal from the super-cutoff blocks 860, 870 from the system 800 of FIG. 8A. Not shown in FIG. 8B is a reset signal, which may be present in some embodiments and may occasionally be activated at chip boot time. Similarly, not shown is toggle input T of FFs in the clock divider at 861, which may be held at 1 in an example embodiment, i.e. always toggling.

FIG. 8C illustrates results of the measured recovered data and clock of the system of FIGS. 8A and 8B as disclosed herein. Graph 812 illustrates the recovered Data_{OUT} and CLK_{OUT}, which indicate a dominant harmonic component at 1 Hz (Data) and 4 Hz (CLK), in line with the 1 Hz and 4 Hz filters 840 and 850 of the system of FIG. 8A (i.e. filtered and clamped at V_{DD} by the hysteresis comparators 860 and 870 as described herein). In an example embodiment, the recovered data and clock CLK may be then fed to the digital sub-system 880 of FIG. 8A, and as set out in FIG. 8B, to compare the incoming photodetector signal with stored device ID. Graph 822 illustrates correct optical pattern matching with chip ID 823, which may trigger the wake-up signal 890 of FIG. 8B to be asserted. For example, when the output Data_{OUT} matches the device ID, as illustrated at reference 823, a wake-up may occur. FIG. 8C also illustrates table 832, showing experimental validation of wakeup receiver operation over typical indoor temperature ranges, showing power consumption at a V_{DD} of 0.5V, for different incident light, and measured BER.

The WuRx measurements in FIG. 8C show the outputs of the data recovery path (845 in FIG. 8A) and the clock recovery path (855 in FIG. 8A), and the related dominant harmonic component of 1 Hz and 4 Hz as enabled by the bandpass filters 840, 850 as described herein. The input signal (around 100 mV peak-to-peak in this example) is amplified by the gain stages, and clamped to V_{DD} by the hysteresis comparators 860, 870, feeding the subsequent logic 880 in FIG. 8A. FIG. 8C also shows correct wake-up detection upon optical transmission of the associated 8-bit ID at 823, e.g., “00011000” in this case.

Compared to conventional circuits, the OTA as disclosed herein, such as the experimental example fabricated in 180-nm CMOS testchip, may exhibit a power consumption of 6.87 pW, which may advantageously be lower than conventional designs in sub-threshold. The area may be lower than conventional designs, and the area-normalized power efficiency may be lower or comparable despite the relatively higher power penalty due to unshared biasing circuitry. Regarding the WuRx system as disclosed herein, in an example embodiment the WuRx circuit power may be lower than prior wake-up receivers, and the area may be smaller than prior conventional receivers. Given the experimental example demonstrated low power consumption of 78 pW, in an example embodiment the WuRx system may keep functioning uninterruptedly when powered by a commercial unregulated 1-mm² solar cell down to 1 lux, which corresponds to moonlight harvesting. Hence, the proposed WuRx as disclosed herein may be able to sustain operation with no energy storage at any practical light condition, enabling near-100% uptime. It will be understood that these experimental values are representative, and may be any other value based on the specific design requirements.

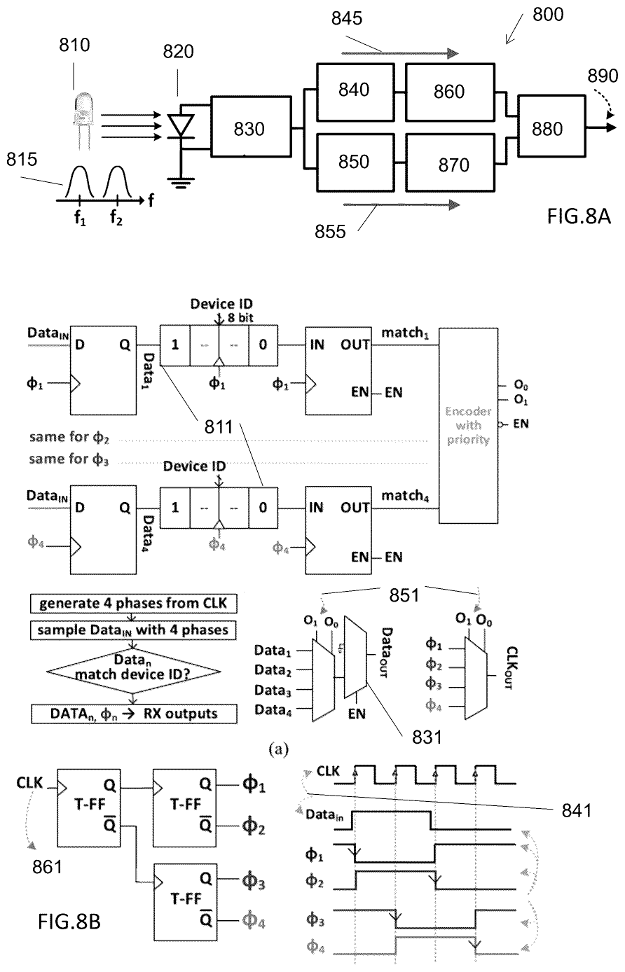

FIG. 9 illustrates experimental measurement results of various circuits as disclosed herein. Graph 910 illustrates frequency response of an open-loop fully-differential operational transconductance amplifier (OTA), such as that of FIG. 4A as described herein. Graph 910 illustrates fully differential gain (dB) against input frequency (Hz). Graph 920 illustrates output spectrum of an open-loop fully-differential operational transconductance amplifier (OTA), such as that of FIG. 4A as described herein. Table 930 illustrates die-to-die variation of a series of open-loop fully-differential operational transconductance amplifier (OTA), such as that of FIG. 4A as described herein. Open-loop single-stage OTA measurements in FIG. 9 show a frequency response with 36.8-dB DC gain and 22.4-Hz gain-bandwidth product (GBW), as allowed under the bias current reduction to the pW range. From the output spectrum, the input-referred noise is 25 μV. The OTA works in a supply voltage range of 0.45-0.8V, and its power and GBW expectedly increase with temperature. It will be understood that these experimental values are representative, and may be any other value based on the specific design requirements.

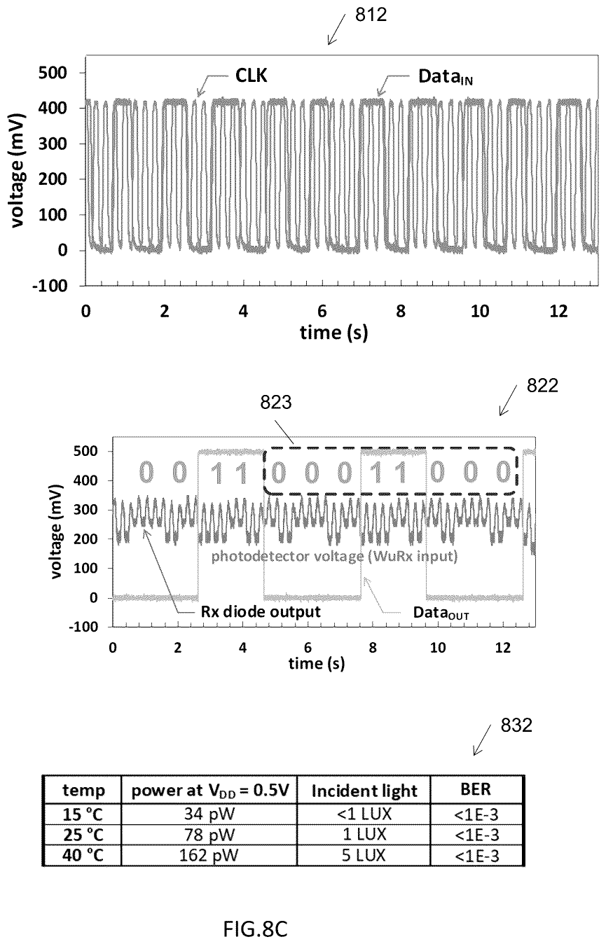

FIG. 10 illustrates a graph 1010 of frequency response of the closed-loop programmable gain amplifier, such as the PGA of FIG. 7B and FIG. 8A for two gain settings.

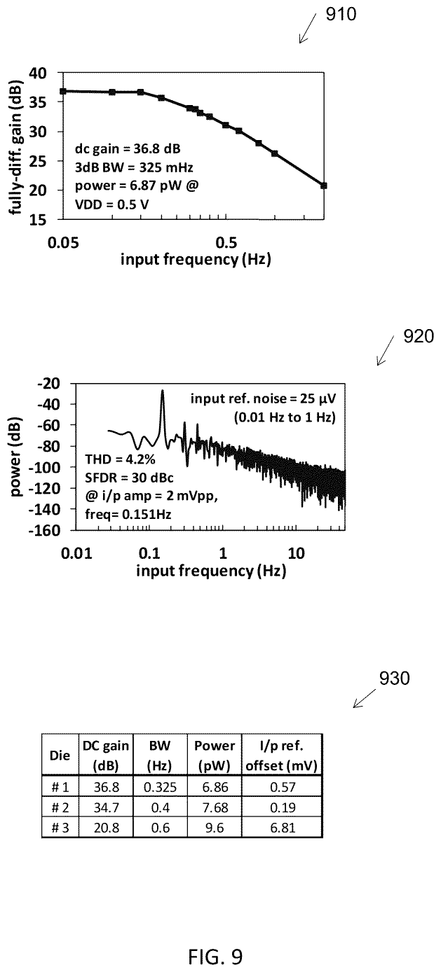

FIG. 11 illustrates a graph 1110 of frequency response of the two bandpass filters, such as those in FIG. 7A and FIG. 8A.

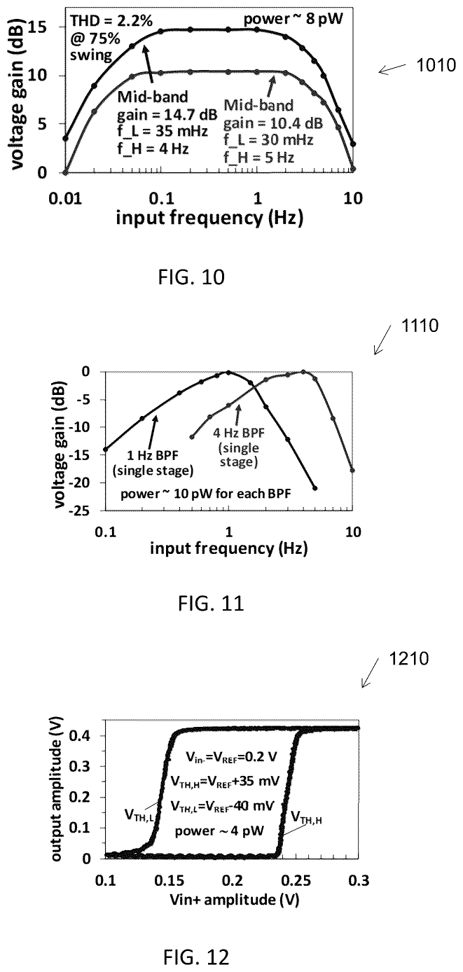

FIG. 12 illustrates a graph 1210 of input-to-output response of the comparator with hysteresis, such as those of FIG. 6 and FIG. 8A. V_{TH,L} and V_{TH,H} are indicated, showing low and high thresholds that differ by ~40 mV from the center value.

As shown in FIG. 10, the PGA, for example the PGA in FIGS. 7B and 8A, has a harmonic distortion, which in an experimental example may have a harmonic distortion of 2.2% at 75% input swing and power of 8 pW including the biasing circuitry. As shown in FIG. 11, similar power of 10 pW is achieved in an experimental example for the two closed-loop bandpass filters, such as the bandpass filters in FIG. 7A and FIG. 8A, with center frequency of 1 Hz and 4 Hz. The hysteresis comparator as disclosed herein, for example in FIG. 6 and FIG. 8A, may, in an experimental example, consume 4 pW and have lower and higher thresholds of −40 and +35 mV respectively. It will be understood that these experimental values are representative, and may be any other value based on the specific design requirements.

In an example embodiment, a circuit 201 is provided, for example as illustrated in FIG. 2B, comprising a current mirror 201 comprising three transistor stacks, a first transistor stack 211, a second transistor stack 221, and a third transistor stack 241. In an example embodiment, each transistor stack 211, 221, 241, comprises one NMOSFET and one PMOSFET, for example as illustrated in FIG. 2 as 210 and 220, and enables super-cutoff transistor operation with a negative NMOSFET gate-source voltage or a PMOSFET source-gate voltage without requiring a bias voltage that is lower than 0 V or a bias voltage higher than a supply voltage. In an example, the first stack 211 conducts input current via a negative feedback loop 231 enabled by the second stack 221, and the third stack 241 replicates the input current Iᵢₙ as an output current Iₒᵤₜ.

In an example embodiment, the circuit may further comprise a bias current generator or current reference circuit 300, for example as shown in FIG. 3A or FIG. 3B, with transistor operation in super-cutoff having temperature compensation and digital tuning, being configured to increase an internally generated control voltage V₄ in proportion to temperature value, in order to compensate the strong temperature dependence of the output current source within the generator.

In an example embodiment, a super-cutoff level shifter 212, 222 as illustrated in FIG. 3C may be provided. The super-cutoff level shifter 212, 222 may be configured to downshift or upshift a voltage waveform based on a voltage value applied between a gate and a source terminal of the level shifter.

In an example embodiment, a super-cutoff operational transconductance amplifier (OTA) is provided, for example circuit 400 as shown in FIG. 4A, or circuit 401 as shown in FIG. 4B. In an example embodiment, the OTA may be for analog signal processing applications, wherein the current mirror with three transistor stacks (211, 221, 231), the bias current generator (300), and the super-cutoff level shifter (212, 222) enable super-cutoff operation within the OTA.

In an example embodiment, there is provided a super-cutoff common mode feedback circuit, such as that disclosed in regard to circuit 400 and FIG. 4A, or circuit 401 and FIG. 4B. The super-cutoff common mode feedback circuit may be based on an NMOSFET-PMOSFET stack, such as the stack 200 of FIG. 2A as described herein, for enabling-fully differential operation based on a comparison of the output common mode voltage with an internally generated bias voltage.

In an example embodiment, a circuit is disclosed, comprising a voltage-independent super-cutoff pseudo-resistor, such as 500 as shown in FIG. 5, formed by a stack of transistors 510, wherein voltages applied to the gate terminal of each transistor MA, MB in the stack of transistors 510 is controlled through a voltage level shifting operation, such as via level shifters 520, 530. In an example embodiment, a super-cutoff hysteresis comparator is provided, such as the super-cutoff hysteresis comparator 600 of FIG. 6. In an example embodiment, the super-cutoff hysteresis comparator 600 may use a bias current generator 610 and a NMOS-PMOS stack 601, the comparator 600 configured to provide a digital output signal indicating whether an input signal is above or below a set of hysteresis thresholds. In an example embodiment, a second or higher-order super-cutoff filter is provided, such as filter 700 of FIG. 7A. In an example embodiment, the second or higher-order super-cutoff filter 700 may be implemented by the super-cutoff pseudo resistor 500 and a super-cutoff operational transconductance amplifier (OTA) 400, the filter 700 configured for enhancing the performance of the circuit by filtering out unwanted frequencies. In an example embodiment, a super-cutoff programmable gain amplifier may be provided, for example the gain amplifier 701 as shown in FIG. 7B. In an example embodiment, the amplifier 701 may comprise the OTA 400 and being configured to provide digitally-programmable amplification of signals.

In an example embodiment, a circuit is provided to function as an ultra-low-power optical wake-up receiver system, for example the optical wake-up receiver system 800 of FIG. 8A to 8C. In an example embodiment, the optical wake-up receiver system may receive an optically modulated signal, comprising data and clock signals, from a basestation 810 through a photo-detector 820, wherein the signal may be processed by the super-cutoff programmable gain amplifier 830, the or a super-cutoff filter for example bandpass filters 840, 850, and the or a comparator blocks, such as the hysteric comparators 860, 870. In an example embodiment, this may allow for the recovery of both the data and clock signals. In an example embodiment, the optical wake-up receiver system may further include a digital logic section, such as digital logic 880, that may continuously compare a received data with a stored device ID until a matching data is received, which may trigger an assertion of a wake-up signal.

Non-limiting advantages of the methods and systems as disclosed herein may include: Super-cutoff current mirrors—The current mirror as disclosed herein may enable super-cutoff operation by pairing two NMOS-PMOS stacks 211 (M1-M2) and 221 (M3-M4), where 211 (M1-M2) conduct the input current Iᵢₙ thanks to the negative feedback loop (adjusting the gate voltage of M1-M3 accordingly) in FIG. 2B. The stack 221 (M3-M4) replicates the current in 211 (M1-M2) to ultimately mirror the input current to the output with the intended current ratio set via ordinary ratioed sizing in M1-M4. The super-cutoff common-source gain stage 241 (M5-M6), employing another NMOS-PMOS stack, may enforce negative feedback 231, introducing a gain that further reduces the small-signal input resistance.

Ultra-low power current reference—In an example embodiment, a bias current generator with transistor operation in super-cutoff having temperature compensation and digital tuning-adjustability is disclosed in regard to FIG. 3A and FIG. 3B. The bias current generator being configured to increase an internally generated control voltage in proportion to temperature value, in order to compensate the strong temperature dependence of the output current source within the generator.

Super-cutoff level shifters—The level shifters as disclosed herein, for example in regard to FIG. 3C, are obtained with conventional common-drain stages, although their V_{GS}<0V mandates the use of a PMOS (NMOS) stage for down (up) shifting of voltage waveforms (opposite to common designs with V_{GS}>0V) in order to operate in super-cutoff.

Super-cutoff OTA—Fully differential and single-ended operational transconductance amplifiers (OTA) are disclosed herein, for example in regard to FIG. 4A and FIG. 4B. The OTA utilizing the super-cutoff current mirrors and current references as disclosed herein, and having ultra-low power consumption in pW range, for analog signal processing applications. The fully differential OTA further comprises a super-cutoff common mode feedback (CMFB) circuit.

Super-cutoff pseudo resistor—The voltage-independent super-cutoff pseudo-resistor disclosed herein, for example in regard to FIG. 5, is based on two stacked PMOS transistors where the two gate voltages are dynamically set through up level shifting to maintain V_{SG} negative and constant in the transistor that dominates the overall resistance, depending on the pseudo-resistor voltage V_{A}−V_{B}. If V_{A}−V_{B}>0 (V_{A}−V_{B}<0) V_{A} (V_{B}) is the source of MA (MB) and hence the level shifter MLA (MLB) controls V_{SG} in MA (MB), whereas MB (MA) has 0>V_{SG,B}>V_{SG,A} and its on-resistance is much smaller than MA (MB). This sets the overall resistance to a fixed value set by the V_{GS} of the level shifter, regardless of the voltages V_{A} and V_{B} at the two pseudo-resistor terminals.

Super-cutoff band pass filter—The super-cutoff OTA as disclosed herein, for example in regard to FIG. 4A or FIG. 4B, may be employed to build an ultra-low power band pass filter as shown in FIG. 7A, and FIG. 8A. A power of 10 pW is achieved for the proposed closed-loop bandpass filters with center frequencies of 1 Hz and 4 Hz in an experimental example.

Super-cutoff hysteresis comparator—As disclosed herein, a super-cutoff hysteresis comparator, such as that disclosed in regard to FIG. 6, may be configured to provide a digital output signal indicating whether an input signal is above or below a set of hysteresis thresholds. In an experimental example embodiment, the comparator may only consume 4 pW of power during typical operation.

Super-cutoff programmable gain amplifier—A super-cutoff programmable gain amplifier (PGA) is disclosed, for example in regard to FIG. 7B, using the OTA, such as that disclosed in regard to FIG. 4A or FIG. 4B, for allowing programmable voltage amplification of signals.

Optical wake-up receiver—An ultra-low power wake-up receiver (WuRx) is disclosed herein, for example in regard to FIGS. 8A to 8C. In an example embodiment, the WuRx consumes an overall power of only 78 pW in an experimental example, and is enabled through super-cutoff operation of various analog blocks as disclosed herein. The WuRx system demonstration power is lower than prior wake-up receivers by 5-103× including optical. Its area is 1.4× larger than some prior receivers, and 16.5× smaller than some prior receivers. Given its low consumption of 78 pW, the system keeps functioning uninterruptedly when powered by a commercial unregulated 1-mm² solar cell down to 1 lux, which corresponds to moonlight harvesting. Hence, the WuRx as disclosed herein is able to sustain operation with no energy storage at any practical light condition, enabling near-100% uptime as targeted.

It will be understood that these experimental values are representative, and may be any other value based on the specific design requirements.

Whilst the foregoing description has described exemplary embodiments, it will be understood by those skilled in the art that many variations of the embodiments can be made within the spirit and scope of the invention as defined by the claims. For example, resistive feedback amplifier using the discussed fully differential OTA and pseudo resistors, single-ended OTA based voltage follower, and resistive feedback amplifier, etc. Moreover, features of one or more embodiments may be mixed and matched with features of one or more other embodiments.

1. A super-cutoff current mirror circuit, comprising:
a first transistor stack,
a second transistor stack, and
a third transistor stack,
wherein each transistor stack comprises one NMOSFET and one PMOSFET, and wherein each transistor stack is configured for super-cutoff transistor operation with a negative NMOSFET gate-source voltage or a PMOSFET source-gate voltage,
wherein the circuit is configured such that the first transistor stack conducts input current via a negative feedback loop enabled by the second transistor stack, and the third transistor stack replicates the input current as an output current.

2. The super-cutoff current mirror circuit of claim 1, wherein each transistor stack comprises a respective negative gate-source voltage, or source-gate voltage, without requiring a bias voltage that is lower than 0V, or higher than a supply voltage of the circuit.

3. A bias current generator or current reference circuit, comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current.

4. A super-cutoff operational transconductance amplifier (OTA) circuit for analog signal processing, the OTA circuit configured to have either differential or single-ended output, and comprising:
the super-cutoff current mirror circuit as claimed in claim 1,
a bias current generator or current reference circuit comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current, and
a source-coupled transistor pair to receive an input differential signal to the OTA circuit,
wherein the circuit is configured such that the current mirror, and the bias current generator enable super-cutoff operation within the OTA circuit, and that an output common-mode voltage is restored to a desired level in the OTA with differential configuration.

5. A super-cutoff pseudo resistor circuit, comprising:
a transistor stack, comprising two PMOSFET transistors, or two NMOSFET transistors,
wherein voltages applied to the gate terminal of each transistor in the transistor stack are controlled through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack.

6. The super-cutoff pseudo resistor circuit of claim 5, wherein the circuit is voltage-independent.

7. A super-cutoff up-level or down-level shifter configured to upshift or downshift a voltage waveform based on a voltage value applied between a gate and a source terminal of the up or down level shifter, the up-level shifter or down-level shifter comprising:
a source follower stage, and
a bias current generator or current reference circuit as claimed in claim 3, configured to bias the source follower stage with a super-cutoff current.

8. A super-cutoff hysteresis comparator circuit, comprising:
a pair of super-cutoff current mirror circuits, each super-cutoff current mirror circuit as claimed in claim 1, wherein the pair of super-cutoff current mirror circuits are configured in a cross coupled mode, and
a super-cutoff current reference comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current,
wherein the comparator circuit is configured to provide a digital output signal indicating whether an input signal is above or below a set of hysteresis thresholds.

9. A super-cutoff bandpass filter circuit, comprising:
a first 2^{nd}-order bandpass filter circuit, the first bandpass filter circuit comprising a pair of 2-stage level shifters on each of a respective positive and negative output of the first bandpass filter circuit, each 1-stage and 2-stage level shifter comprising the up or down level shifter as claimed in claim 7; and
a second 2^{nd}-order bandpass filter circuit, the second bandpass filter circuit comprising:
a pair of 2-stage level shifters on respective feedback loops of the second bandpass filter circuit, and
a pair of 1-stage level shifters on each of a respective positive and negative output of the second bandpass filter circuit,
each 2-stage level shifter comprising the up or down level shifter as claimed in claim 7;
wherein the first bandpass filter circuit and the second bandpass filter circuit are arranged in a standalone configuration, or a cascade configuration.

10. An AC coupled super-cutoff programmable gain amplifier, comprising:
the operational transconductance amplifier circuit as claimed in claim 4,
a super-cutoff pseudo resistor circuit comprising: a transistor stack comprising two PMOSFET transistors or two NMOSFET transistors, wherein voltages applied to the gate terminal of each transistor in the transistor stack are controlled through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack, and
a pair of 2-stage level shifters on each of a respective up and down output of the operational transconductance amplifier, each 2-stage level shifter comprising a up or down level shifter configured to upshift or downshift a voltage waveform based on a voltage value applied between a gate and a source terminal of the up or down level shifter, the up-level shifter or down-level shifter comprising:
a source follower stage, and
a bias current generator or current reference circuit configured to bias the source follower stage with a super-cutoff current, the bias current generator or current reference circuit comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current.

11. A super-cutoff wakeup receiver system, comprising:
a photo detector,
a super-cutoff hysteresis comparator circuit comprising:
a pair of super-cutoff current mirror circuits, each super-cutoff current mirror circuit comprising:
a first transistor stack,
a second transistor stack, and
a third transistor stack,
wherein each transistor stack comprises one NMOSFET and one PMOSFET, and wherein each transistor stack is configured for super-cutoff transistor operation with a negative NMOSFET gate-source voltage or a PMOSFET source-gate voltage,
wherein the circuit is configured such that the first transistor stack conducts input current via a negative feedback loop enabled by the second transistor stack, and the third transistor stack replicates the input current as an output current, wherein the pair of super-cutoff current mirror circuits are configured in a cross coupled mode, and
a super-cutoff current reference comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current,
wherein the comparator circuit is configured to provide a digital output signal indicating whether an input signal is above or below a set of hysteresis thresholds,
a super-cutoff bandpass filter circuit comprising:
a first 2nd-order bandpass filter circuit, the first bandpass filter circuit comprising a pair of 2-stage level shifters on each of a respective positive and negative output of the first bandpass filter circuit, each 1-stage and 2-stage level shifter comprising an up or down level shifter configured to upshift or downshift a voltage waveform based on a voltage value applied between a gate and a source terminal of the up or down level shifter, the up-level shifter or down-level shifter comprising:
a source follower stage, and
a bias current generator or current reference circuit configured to bias the source follower stage with a super-cutoff current, the bias current generator or current reference circuit comprising:
a temperature dependent proportional-to-absolute-temperature (PTAT) voltage generator,
a level shifter, wherein the PTAT voltage generator is configured to provide a supply voltage and a gate voltage to transistors of the level shifter,
a common source gain stage to amplify an output of the level shifter, and
a temperature dependent proportional-to-absolute-temperature (PTAT) current source configured to receive the PTAT output voltage of the common source gain stage and provide a temperature compensated current; and
a second 2nd-order bandpass filter circuit, the second bandpass filter circuit comprising:
a pair of 2-stage level shifters on respective feedback loops of the second bandpass filter circuit, and
a pair of 1-stage level shifters on each of a respective positive and negative output of the second bandpass filter circuit,
each 2-stage level shifter comprising the up or down level shifter;
wherein the first bandpass filter circuit and the second bandpass filter circuit are arranged in a standalone configuration, or a cascade configuration, and
a super-cutoff programmable gain amplifier as claimed in claim 10,
wherein the system is configured to:
receive an optically modulated signal, comprising data and clock signals, from a basestation through the photo-detector,
process the signal via the super-cutoff programmable gain amplifier, the super-cutoff bandpass filter, and the hysteresis comparator, allowing for the recovery of both the data and clock signals; and
wherein the system further includes a digital logic section that continuously compares a received data with a stored device ID until a matching data is received, triggering an assertion of a wake-up signal.

12. A super-cutoff resistive feedback amplifier, comprising:
the super-cutoff operational transconductance amplifier (optionally with differential outputs) as claimed in claim 4, and
a super-cutoff pseudo resistor comprising a transistor stack, comprising two PMOSFET transistors, or two NMOSFET transistors,
wherein voltages applied to the gate terminal of each transistor in the transistor stack are controlled through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack, and
wherein the pseudo resistor is arranged in a feedback loop of the operational transconductance amplifier.

13. A super-cutoff single-ended OTA based voltage follower, comprising the super-cutoff operational transconductance amplifier (with single-ended output) as claimed in claim 4, wherein the OTA is arranged in a unity negative feedback loop with unity feedback from the output to the negative input terminal of the OTA, and the external input signal being provided to the positive input terminal of the OTA.

14. A super-cutoff single-ended OTA based resistive feedback amplifier, comprising:
the super-cutoff operational transconductance amplifier (with single-ended output) as claimed in claim 4, and
a super-cutoff pseudo resistors comprising a transistor stack, comprising two PMOSFET transistors, or two NMOSFET transistors,
wherein voltages applied to the gate terminal of each transistor in the transistor stack are controlled through a voltage level shifting operation such that the transistors in the transistor stack operate in a super-cutoff mode where a source-gate voltage is maintained negative for a PMOSFET transistor stack, or a gate-source voltage is maintained negative for a NMOSFET stack, and
wherein the pseudo resistors are arranged in a feedback loop of the operational transconductance amplifier, from the output to the negative input terminal of the OTA, with the external input signal being provided to the positive input terminal of the OTA.

15. A circuit comprising:
the super-cutoff current mirror of claim 1, wherein each transistor stack enables the super-cutoff transistor operation without requiring a bias voltage that is lower than 0 V or a bias voltage higher than a supply voltage; and
a bias current generator or current reference with transistor operation in super-cutoff having temperature compensation and digital tuning, being configured to increase an internally generated control voltage in proportion to temperature value, in order to compensate the strong temperature dependence of the output current source within the generator.

16. The circuit of claim 15, further configured as a super-cutoff operational transconductance amplifier (OTA) for analog signal processing applications, wherein the OTA comprises a source-coupled transistor pair configured to receive an input differential signal to the OTA, and wherein the current mirror with three transistor stacks, and the bias current generator enable super-cutoff operation within the OTA.

17. The circuit of claim 16, further comprising a super-cutoff common mode feedback based on an NMOSFET-PMOSFET stack for enabling-fully differential operation based on a comparison of the output common mode voltage with an internally generated bias voltage.

18. A circuit comprising:
the voltage-independent super-cutoff pseudo-resistor circuit of claim 5, wherein the super-cutoff pseudo-resistor is voltage-independent;
a super-cutoff hysteresis comparator using a bias current generator and a NMOS-PMOS stack, the comparator configured to provide a digital output signal indicating whether an input signal is above or below a set of hysteresis thresholds;
a second or higher-order super-cutoff filter implemented by the super-cutoff pseudo resistor and a super-cutoff operational transconductance amplifier (OTA), the filter configured for enhancing the performance of the circuit by filtering out unwanted frequencies; and
a super-cutoff programmable gain amplifier, the amplifier comprising the OTA and being configured to provide digitally-programmable amplification of signals.

19. The circuit of claim 18, further configured to function as an ultra-low-power optical wake-up receiver system, wherein the system receives an optically modulated signal, comprising data and clock signals, from a basestation through a photo-detector, wherein the received signal is processed by the super-cutoff programmable gain amplifier, the super-cutoff filter, and the comparator blocks, allowing for the recovery of both the data and clock signals; and wherein the system further includes a digital logic section that continuously compares the received data with a stored device ID until a matching data is obtained, triggering an assertion of a wake-up signal.

20-25. (canceled)
